(19) United States
(12) Patent Application Publication
(10) Pub. No.: US 2017/0025255 A1
(43) Pub. Date: Jan. 26, 2017

(54) PLASMA PROCESSING APPARATUS

(71) Applicant: Hitachi High-Technologies Corporation, Tokyo (JP)

(72) Inventors: Takumi TANDOU, Tokyo (JP); Kenetsu YOKOGAWA, Tokyo (JP)

(21) Appl. No.: 15/203,851

(22) Filed: Jul. 7, 2016

(30) Foreign Application Priority Data
Jul. 23, 2015 (JP) 2015-145405

(51) Int. Cl. H01J 37/32

(52) U.S. Cl. CPC H01J 37/32532; H01J 37/32009; H01J 37/3244; H01J 37/32715; H01J 2237/334

(57) ABSTRACT

A sample stage includes a metallic electrode block to which high-frequency power is supplied from a high-frequency power supply, a dielectric heat generation layer which is disposed on a top surface of the electrode block and in which a film-like heater receiving power and generating heat is disposed, a conductor layer which is disposed to cover the heat generation layer, a ring-like conductive layer which is disposed to surround the heat generation layer at an outer circumferential side of the heat generation layer and contacts the conductor layer and the electrode block, and an electrostatic adsorption layer which is disposed to cover the conductor layer and electrostatically adsorbs a sample. The conductor layer and the ring-like conductive layer have dimensions more than a skin depth of a current of the high-frequency power and the electrode block is maintained at a predetermined potential during processing of the sample.

### BACKGROUND OF THE INVENTION

1. Field of the Invention

The present invention relates to a plasma processing device that performs minute processing on a sample such as a wafer in a semiconductor manufacturing process and more particularly, to a plasma processing device that includes a sample stage to hold and fix a semiconductor wafer.

2. Description of the Related Art

According to a trend of miniaturization of a semiconductor device, processing precision required for an etching process of a sample becomes higher every year. To perform high-precision processing on a minute pattern of a surface of a wafer using a plasma processing device, temperature management of the wafer surface at the time of etching becomes important.

Recently, to meet a demand for improving shape precision, there is a need for technology for rapidly and minutely adjusting the temperature of the wafer according to an etching step during a process. Conventionally, it is considered that the temperature of a surface of a sample stage on which the wafer is disposed and which contacts the wafer is increased or decreased to change the temperature of the surface of the wafer disposed in a decompressed processing chamber, in the plasma processing device that processes a film structure having a plurality of layers becoming a circuit structure of a top surface of the semiconductor wafer using plasma formed in the processing chamber in a vacuum vessel.

The sample stage disposed in the processing chamber in a vacuum state generally has a metallic base of a circular cylindrical or discoid shape in which a cooling medium flow channel through which a cooling medium of which an inner side is adjusted to a predetermined temperature circulates or a heater receiving power and generating heat is disposed and a dielectric film that is disposed to cover a surface of the base and is provided with a film-like electrode applied with a direct-current voltage to electrostatically adsorb the wafer and configures an electrostatic chuck to adsorb and hold the wafer disposed on a top surface of the dielectric film. In addition, gas having heat transference such as He is supplied between a back surface of the electrostatically adsorbed wafer and the top surface of the dielectric film to enable heat transfer between the cooling medium or the heater in the base of the sample stage in the vacuum state and the wafer and the temperature of the wafer is adjusted by a heat exchange between them.

The related technology is disclosed in JP-2008-527694-A. JP-2008-527694-A discloses a configuration of a sample stage in which a film-like or plate-like heater, a metal plate, and an electrostatic adsorption film are sequentially disposed on a metallic electrode block of a discoid shape internally including a cooling medium flow channel through which a cooling medium circulates. By this configuration, an output of the heater is adjusted, so that temperatures of a surface of the sample stage and the wafer disposed on the sample stage increase or decrease and become values in a desired range.

In addition, technology for reducing a variation of a heat passage amount for an in-plane direction in the sample stage by suppressing a variation of a thickness for an in-plane direction in a top surface of an adhesive layer to adhere the heater to a top surface of the electrode block or flattening top and bottom surfaces of the metal plate and improving uniformity of the temperature of the wafer or the sample stage for the in-plane direction is disclosed in JP-2008-527694-A.

Meanwhile, as disclosed in JP-2008-527694-A, when the heater or the metal plate is disposed on the electrode block, a lateral surface of the heater or the metal plate is exposed to the plasma. As a result, the lateral surface is altered or cut with a mutual action with the plasma, and a bad influence is exerted on a distribution of the temperature of the wafer or particles of a cut member are scattered to the processing chamber and adhere to other place of the processing chamber or the wafer and contamination occurs. To resolve this problem, as disclosed in JP-9-260474-A, a configuration in which a lateral surface of a film-like member of a sample stage including the film-like member to adjust a temperature is covered with an insulator to protect the film-like member from the plasma is known. In this related art, the configuration is used, so that the lateral surface is protected from the plasma and temperatures of a surface of the sample stage and a surface of the wafer are adjusted to values in a desired range.

### SUMMARY OF THE INVENTION

In the related art, a problem occurs because the following points are not sufficiently considered.

That is, in a field of a plasma etching device, generally, charged particles such as ions of the plasma are caused to collide with a process target layer on the wafer during processing of the wafer, etching of a predetermined direction on the process target layer is accelerated, and a desired opening shape is obtained. For this reason, high-frequency power of a desired frequency is supplied to the electrode block and a bias potential is formed on the dielectric film of the electrostatic chuck or the top surface of the wafer disposed on the dielectric film, so that the charged particles are attracted to the top surface of the wafer by a potential difference of a plasma potential and the bias potential. In addition, when the heater is disposed on the electrode block of the sample stage, power is supplied to the heater through a path different from a path of the high-frequency power for the bias potential formation and a high-frequency filter to block the high-frequency power is disposed on a path for feeding the heater.

Generally, the magnitude of the frequency of the high-frequency power for the basis potential formation affects etching performance. For example, when the frequency is increased, a selection ratio of a mask is improved in a process for etching an insulating film, because ion energy incident on the wafer is monochromatized. As a result, the etching performance is improved. Meanwhile, an amount of heat generation increases in a place between the heater on the path for feeding the heater and the high-frequency filter.

That is, a coaxial cable is generally used in a line for feeding the heater and a leak current between a center conductor and an external conductor in the coaxial cable increases when the frequency of the high-frequency power increases. As a result, heat generation from the coaxial cable increases. For this reason, the wafer cannot be processed using the high-frequency power of the high frequency and process performance is deteriorated. Such a problem is not considered in the related art.

An object of the present invention is to provide a plasma processing device that suppresses heat generation in a path for feeding a heater in a sample stage including the heater and improves process performance.

The object is achieved by a plasma processing device including: a processing chamber which is disposed in a vacuum vessel and is compressed internally; a sample stage which is disposed in a lower portion in the processing chamber and on which a sample of a process target is disposed and held; and a mechanism for forming plasma in the processing chamber, wherein the sample stage includes a metallic electrode block to which high-frequency power is supplied from a high-frequency power supply, a dielectric heat generation layer which is disposed on a top surface of the electrode block and in which a film-like heater receiving power and generating heat is disposed, a conductor layer which is disposed to cover the heat generation layer, a ring-like conductive layer which is disposed to surround the heat generation layer at an outer circumferential side of the heat generation layer, contacts the conductor layer and the electrode block, and electrically connects the conductor layer and the electrode block, and an electrostatic adsorption layer which is disposed to cover the conductor layer and generates electrostatic force to electrostatically adsorb the sample disposed on a top surface thereof, and the conductor layer and the ring-like conductive layer have dimensions more than a skin depth of a current of the high-frequency power and the electrode block is maintained at a predetermined potential during processing of the sample.

According to the present invention, a heater layer is shielded with a conductive material and bias power (high-frequency current) applied to an electrode block can be suppressed from flowing to a heater line. That is, because a current of high-frequency power flows through a surface of a conductor by a skin effect, a heater is covered with a member made of a conductive material having a thickness more than a skin depth. As a result, the current of the high-frequency power is suppressed from flowing to the heater, heat generation is suppressed in a line for feeding the heater, high-frequency power for bias formation with a frequency of a wider range can be used, and etching performance is improved.

In addition, because the electrode block and a shield plate are electrically connected, a voltage is suppressed from becoming hard to be applied to a sheath on a wafer by impedance of the heat layer, when bias power is applied to the electrode block. For example, even when the heater is formed in a lamination structure and only a thickness of an insulating material in the heater layer is increased, impedance between the electrode block and the shield plate is not affected and a voltage of the high-frequency power is applied efficiently to the sheath on a top surface of the wafer, regardless of a configuration of the heater. As a result, a degree of freedom in designing the heater increases and a temperature of the heater can be adjusted with high precision.

### BRIEF DESCRIPTION OF THE DRAWINGS

Other objects and advantages of the invention will become apparent from the following description of embodiments with reference to the accompanying drawings in which:

FIG. 1 is a longitudinal cross-sectional view schematically illustrating a configuration of a plasma processing device according to an embodiment of the present invention;

FIG. 2 is a longitudinal cross-sectional view schematically illustrating a configuration of a sample stage of a plasma processing device according to the related art;

FIG. 3 is a longitudinal cross-sectional view schematically illustrating a configuration of a sample stage of the plasma processing device according to the embodiment illustrated in FIG. 1;

FIG. 4 is a longitudinal cross-sectional view schematically illustrating a configuration of the sample stage of the plasma processing device according to the embodiment illustrated in FIG. 1;

FIGS. 5A and 5B are longitudinal cross-sectional views schematically illustrating a configuration of a sample stage of a plasma processing device according to a modification of the embodiment illustrated in FIG. 1;

FIG. 6 is a longitudinal cross-sectional view schematically illustrating a configuration of a heat generation layer of the sample stage according to the modification illustrated in FIGS. 5A and 5B;

FIG. 7 is a longitudinal cross-sectional view schematically illustrating a configuration of a sample stage of a plasma processing device according to another modification of the embodiment illustrated in FIG. 3; and

FIG. 8 is a longitudinal cross-sectional view schematically illustrating a configuration of a sample stage of a plasma processing device according to other modification of the embodiment illustrated in FIG. 3.

### DESCRIPTION OF THE PREFERRED EMBODIMENTS

Preferred embodiments of the present invention will be described in detail below with reference to the accompanying drawings, wherein like reference numerals refer to like parts throughout.

### First embodiment

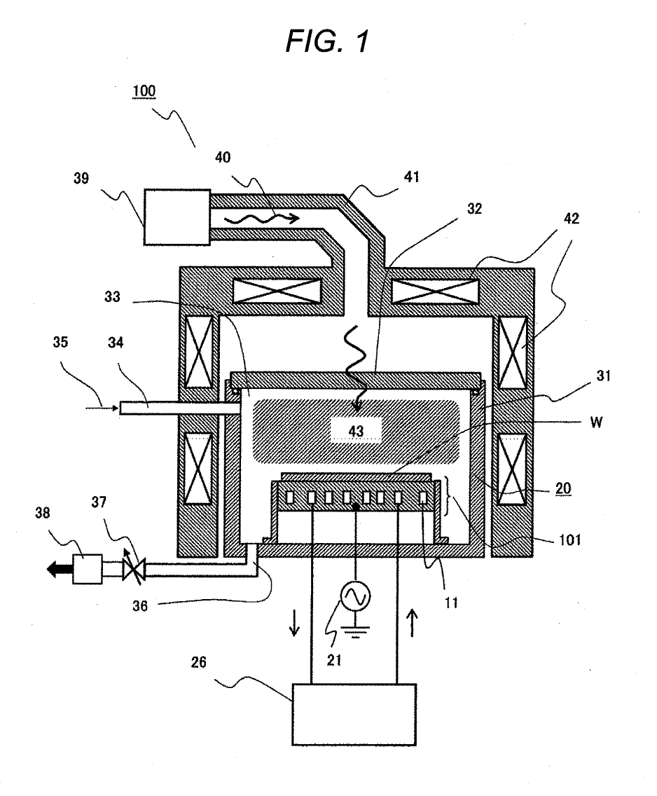

Hereinafter, a first embodiment of the present invention will be described using FIGS. 1 to 7. FIG. 1 is a longitudinal cross-sectional view schematically illustrating a configuration of a plasma processing device according to an embodiment of the present invention. Particularly, the plasma processing device of FIG. 1 is a plasma etching device that introduces an electric field of a microwave band and a magnetic field formed by coils disposed around a vacuum vessel into a processing chamber disposed in the vacuum vessel via a waveguide, excites process gas supplied to the processing chamber by electron cyclotron resonance (ECR) by a mutual action of the electric field and the magnetic field, and forms plasma.

In FIG. 1, a plasma processing device 100 includes a vacuum vessel 20 that is provided with a processing chamber 33 of which an inner side is decompressed to a predetermined vacuum degree suitable for a process, a plasma formation unit that is disposed on and beside the vacuum vessel 20, forms an electric field or a magnetic field to form plasma, and supplies the plasma to the processing chamber 33, and an exhaust unit that is disposed below the vacuum vessel 20, communicates with the processing chamber 33 via an exhaust port 36 below the processing chamber 33, and includes a vacuum pump such as a turbo-molecular pump 38. The vacuum vessel 20 includes a metallic processing chamber wall 31 with a circular cylindrical shape that is disposed to surround outer circumference of the processing chamber 33 with a circular cylindrical shape and a lid member 32 with a discoid shape that is disposed on an upper end portion of a circular shape of the processing chamber wall 31 and includes a dielectric capable of transmitting an electric field of a microwave band, such as quartz glass.

A sealing member such as an O-ring is interposed between a bottom surface of an outer circumferential edge portion of the lid member 32 and an upper end portion of the processing chamber wall 31 to connect or couple the lid member 32 and the processing chamber wall 31, so that the sealing member is deformed and inner and outer sides of the processing chamber 33 are airtightly sealed. A circular cylindrical sample stage 101 where a sample W (in this example, a semiconductor wafer) is disposed on a circular top surface is disposed on a lower portion of an inner side of the processing chamber 33 and a gas introduction pipe 34 having an opening for introducing process gas 35 to execute an etching process into the processing chamber 33 is disposed on an upper portion of the processing chamber 33 on the sample stage.

The exhaust port 36 is disposed on a bottom surface of the processing chamber 33 below the sample stage 101 and the process gas 35 introduced into the processing chamber 33, reaction products generated by etching, or particles of the plasma 43 are exhausted via the exhaust port 36. The exhaust port 36 communicates with an inlet of the turbo-molecular pump 38 configuring the exhaust unit via a pipe for exhaust.

A pressure adjustment valve 37 including a plurality of plate-like flaps configured to rotate around a rotation shaft disposed in a transverse direction of an axis of a passage in the pipe and increase or decrease a flow channel cross-section of the pipe is disposed on the pipe. Angles of the flaps of the pressure adjustment valve 37 increase or decrease according to a command signal from a control device not illustrated in the drawings and an opening of the pipe is adjusted, so that an exhaust flow amount or an exhaust speed of the processing chamber 33 by the exhaust port 36 is adjusted, and an internal pressure of the processing chamber 33 is adjusted to a value in a predetermined range. In this embodiment, the internal pressure of the processing chamber 33 is adjusted to a predetermined value in a range of about several Pa to tens of Pa.

A waveguide 41 configuring the plasma formation unit and a microwave oscillator 39 such as a magnetron disposed on an end portion of the waveguide 41 and forming an electric field 40 of a microwave are provided on the processing chamber 33. The electric field 40 of the microwave generated by the microwave oscillator is introduced into the waveguide 41 and propagates through a portion having a rectangular cross-section and a portion having a circular cross-section connected to the portion having the rectangular cross-section, the electric field 40 is amplified in a mode of a predetermined electric field in a circular cylindrical space for resonance connected to a lower end portion of the waveguide 41 and having a larger diameter than the waveguide 41, and the electric field of the corresponding mode transmits the lid member 32 disposed on the processing chamber 33 and configuring the upper portion of the vacuum vessel 20 and is introduced into the processing chamber 33 from the upper side.

Solenoid coils 42 disposed to surround the lid member 32 and the processing chamber wall 31 are provided on the lid member 32 and around an external wall of the processing chamber wall 31. If a magnetic field generated by the solenoid coils 42 is introduced into the processing chamber 33, atoms or molecules of the process gas 35 introduced into the processing chamber 33 are excited by the ECR caused by a mutual action of the electric field 40 of the microwave and the magnetic field and the plasma 43 is generated in a space of the processing chamber 33 on the sample stage 101 or the sample W on a top surface thereof. The plasma 43 faces the sample W and as described above, high-frequency power of a predetermined frequency output from a high-frequency power supply 21 is supplied to a metallic electrode in the sample stage 101, charged particles of the plasma 43 are attracted by a bias potential formed on the sample W, and the etching process is executed on a process target layer of a film structure previously disposed on the top surface of the sample W.

In this embodiment, a configuration in which a temperature of the sample stage 101 is adjusted to realize a temperature of the sample W in a predetermined range suitable for a process during processing of the sample W to be the semiconductor wafer is included. A temperature adjustment unit 26 disposed outside the vacuum vessel 20 and having a function of adjusting a temperature of a cooling medium to a value in a set range and a cooling medium flow channel 11 disposed in the sample stage 101 are connected by a pipe and configure a circulation path, the cooling medium of which the temperature has been adjusted by the temperature adjustment unit 26 is supplied to the cooling medium flow channel 11 in an electrode block via the pipe, a heat exchange is performed between the cooling medium passing through the inner side and the electrode block thermally connected to the sample W, and the temperature of the electrode block or the sample W disposed on the electrode block is adjusted to become a value in a desired range.

If a detector not illustrated in the drawings detects completion of the etching process, using known technology such as analysis of emission of the plasma 43, supply of the high-frequency power from the high-frequency power supply 21 and supply of the electric field and the magnetic field are stopped, the plasma 43 is extinguished, and the etching process is stopped. Then, the sample W is carried out from the processing chamber 33 and chamber cleaning is performed.

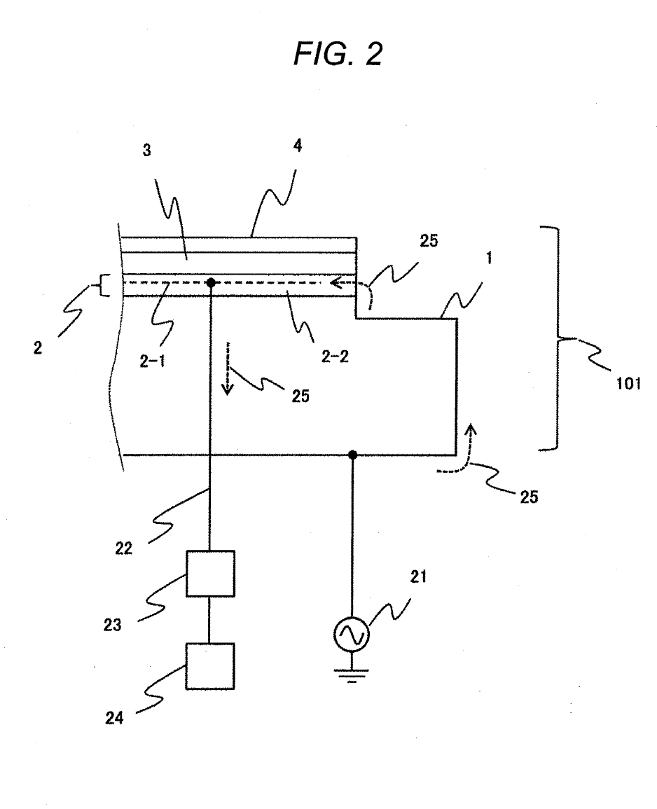

Hereinafter, a configuration of the sample stage 101 according to this embodiment will be described using FIG. 2 and the following drawings. First, a configuration of a sample stage of a plasma processing device according to the related art will be described using FIG. 2.

FIG. 2 is a longitudinal cross-sectional view schematically illustrating the configuration of the sample stage of the plasma processing device according to the related art. In FIG. 2, a cross-sectional taken along a surface of a vertical direction including a center axis of the sample stage 101 having a circular cylindrical or discoid shape and a radius of any direction from the center axis is illustrated.

In FIG. 2, the sample stage 101 includes a metallic electrode block 1 which is provided with a cooling medium flow channel not illustrated in the drawings, through which a heat exchange medium (hereinafter, referred to as a “cooling medium”) circulates, and has a discoid or circular cylindrical shape, a heater layer 2 which is a layer disposed on the electrode block 1, a metal plate 3 which is disposed on the heater layer 2, and an electrostatic adsorption layer 4 which is a dielectric layer disposed on a top surface of the metal plate 3. When the plasma processing device 100 etches the sample W, ions are caused to be incident on a surface of the sample W disposed on a top surface of the electrostatic adsorption layer 4 on the sample stage 101. Therefore, a configuration in which the high-frequency power to form the bias potential is supplied to the electrode block 1 is general. In this example, the high-frequency power for bias formation is supplied from the high-frequency power supply 21 that is electrically connected to the electrode block 1 and outputs power of a predetermined frequency.

Meanwhile, a resistor 2-1 for heat generation configuring the heater layer 2 is electrically connected to a heater power supply 24 via a heater feed line 22 including a coaxial cable disposed in a through-hole (not illustrated in the drawings) disposed in the electrode block 1 and connected to the resistor 2-1 for the heat generation in the heater layer 2 via a connector. A high-frequency filter 23 including a low-pass filter including a capacitor to block the high-frequency power for the bias formation not to flow to the heater power supply 24 is disposed on the heater feed line 22.

A high-frequency current 25 (when a high-frequency power-supply voltage is plus) of the high-frequency power from the high-frequency power supply 21 flows from the high-frequency power supply 21 to the resistor 2-1 for the heat generation via the electrode block 1 and flows to the heater feed line 22. However, the high-frequency current 25 is suppressed from flowing to the heater power supply 24, by the high-frequency filter 23. For this reason, the high-frequency power for the bias potential formation supplied to the electrode block 1 is supplied to a member to be an inner wall surface of the processing chamber 33 and facing the plasma 43, that is, a member having a predetermined potential, for example, a ground potential and the high-frequency current 25 flows in a direction of the sample W (not illustrated in the drawings) such as a direction of the metal plate 3 and the electrostatic adsorption layer 4 and flows in a direction of a wall surface in the processing chamber 33.

A frequency of the high-frequency power for the bias potential formation affects etching performance. For example, when the frequency is increased, ion energy incident on the wafer is monochromatized. For this reason, in a process for etching an insulating film, a mask selection ratio is improved and the etching performance is improved. Meanwhile, when the frequency is increased, the heat is generated in the heater feed line 22 between the resistor 2-1 for the heat generation and the high-frequency filter 23.

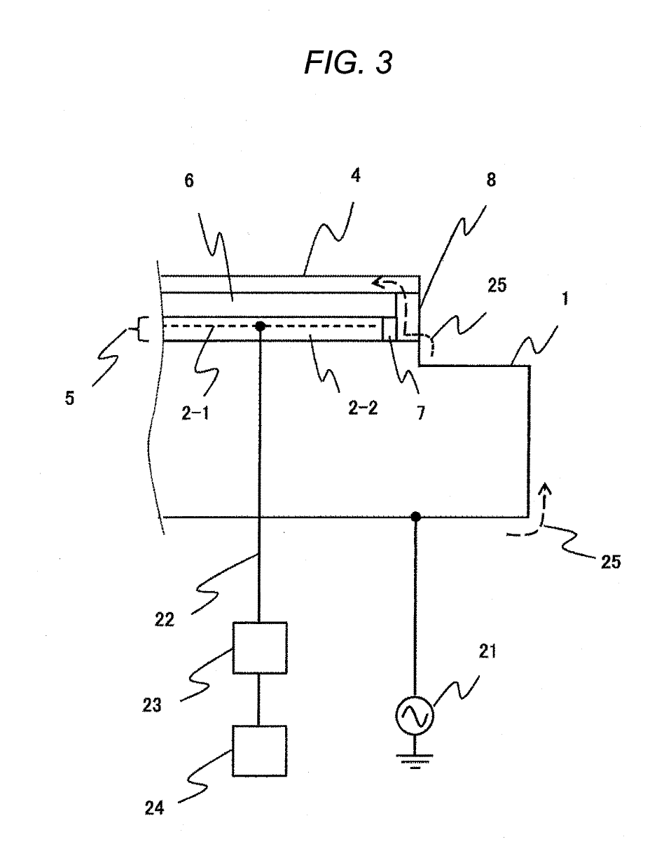

That is, when the frequency of the high-frequency power for the bias formation is increased to improve the etching performance of the sample W disposed on the sample stage 101 including the heater, the heat generation of the heater feed line 22 causes a problem. To resolve the problem, in this embodiment, a configuration to be described below is included. FIG. 3 is a longitudinal cross-sectional view schematically illustrating a configuration of the sample stage of the plasma processing device according to the embodiment illustrated in FIG. 1.

In FIG. 3, the sample stage 101 according to this embodiment includes the metallic electrode block 1 that is provided with a cooling medium flow channel 11 and has a convex portion where a top surface becomes high at a center portion and a recessed portion where a portion of an outer circumferential side becomes low and a heat generation layer 5, a shield layer 6, a conductive layer 7, an insulating layer 8, and an electrostatic adsorption layer 4 that configure a plurality of layers disposed on a top surface of the convex portion of the electrode block 1 to cover the electrode block 1. The heat generation layer 5 is typically composed of the heater layer 2. In this embodiment, the film-like resistor 2-1 for the heat generation which is formed of stainless or tungsten and in which a portion of a circular shape similar to a shape of the sample W or a portion of a circular arc shape to be disposed multiply is disposed in a circular region is disposed to be included in an insulator film 2-2 made of ceramics such as alumina and yttria or resin such as polyimide.

As the heat generation layer 5, a Peltier element may be used. In this embodiment, a heater having a metallic film is used in the heat generation layer 5.

The shield layer 6 to be a conductive layer is disposed between the heat generation layer 5 and the electrostatic adsorption layer 4 configuring a placement surface of the sample W and made of a dielectric. As the shield layer 6, a conductive layer may be formed by spraying or plating or a metallic discoid member such as aluminum and molybdenum may be used, instead of the film-like member.

A conductive layer 7 that covers the heat generation layer 5, is disposed on a top surface of the convex portion of the electrode block 1 in a ring shape, and is composed of a conductive member is disposed on the outside of an outer circumferential edge of the heat generation layer 5. The shield layer 6 adheres to the metallic electrode block 1 with a discoid or circular cylindrical shape, with the conductive layer 7 between the electrode block 1 and a portion of the outer circumferential side thereof. The conductive layer 7 may be an applied conductive adhesive or may be a film formed by spraying a ceramic material mixed with a conductive material. In addition, the conductive layer 7 may be a conductive pin of a spring type and a structure such as a ring member made of a conductor.

The heat generation layer 5 is surrounded with the shield layer 6 and the conductive layer 7. Meanwhile, if the conductive layer 7 disposed on an outer circumferential portion of the shield layer 6 is exposed to the plasma 43, active particles such as radical or charged particles such as ions in the plasma 43 and the conductive layer 7 act mutually and are altered by a chemical reaction, products are volatilized, physical cutting such as sputtering is generated, conductivity of the conductive layer 7 is changed temporally, and the surface of the processing chamber 33 or the sample W is contaminated due to particles scattered to the processing chamber 33 and originated from the conductive layer 7.

To suppress this, in this example, the insulating layer 8 disposed in a ring shape to surround the conductive layer 7 and configured to include a material of a dielectric or an insulator having relatively large plasma resistance is disposed on the outer circumferential side of the conductive layer 7. In this example, the insulating layer 8 is a layer to cover a surface of the outer circumferential side of the conductive layer 7 and a wall of the outer circumferential side of the shield layer 6 on the conductive layer 7 and a top surface of the insulating layer 8 is connected to a bottom surface of an outer circumferential edge portion of the electrostatic adsorption layer 4. The insulating layer 8 is interposed between the electrostatic adsorption layer 4 and the top surface of the convex portion of the electrode block 1 and surrounds the conductive layer 7, the shield layer 6, and the heat generation layer 5 of the inner side with respect to the processing chamber 33 or the plasma 43, for protection. In the insulating layer 8, for example, silicon, epoxy, and fluororubber are used.

The insulating layer 8 may be configured using a member of a ring shape made of an elastic material, the insulating layer 8 may be biased on an outer circumferential surface of the conductive layer 7 using elasticity, and the insulating layer 8 may be attached removably. By this configuration, even when an etching process condition where the insulating layer 8 is rapidly consumed is used, the insulating layer 8 can be exchanged in short time and a non-operation time in which the vacuum vessel 20 is exposed to air and the sample W is not processed, for maintenance and inspection, can be shortened.

In addition, the insulating layer 8 may have a structure of a plurality of layers configured from layers of different materials with respect to a radial direction of the electrode block 1, the shield layer 6, and the electrostatic adsorption layer 4, an inner layer may adhere to the shield layer 6 and the conductive layer 7, and only an outer layer may be removed. As a result, even when the outer layer of the insulating layer 8 is removed at the time of maintenance work, the conductive layer 7 is suppressed from being exposed to the outside and it is possible to prevent a situation where components of the conductive layer 7 are scattered to the processing chamber 33 and an inner portion or the sample W is contaminated, when the vacuum vessel 20 is airtightly configured and the processing chamber 33 is decompressed after the maintenance work ends.

In the electrostatic adsorption layer 4, a film-like electrode disposed over a region of a circular shape according to the shape of the sample W not illustrated in the drawings is disposed in a film configured using a dielectric material of ceramics such as alumina and yttria, a charge is formed and accumulated in a dielectric film on the electrode for the electrostatic adsorption by applying a direct-current voltage to the electrode for the electrostatic adsorption, and the wafer disposed on a top surface of the dielectric film is electrostatically adsorbed by generated electrostatic force. The electrostatic adsorption layer 4 may be formed by sintering the dielectric material provided with the film-like electrode and formed in a discoid shape or may be formed by spraying ceramic particles or metal particles onto the top surface of the shield layer 6.

By the configuration according to this embodiment, the heat generation layer 5 is covered with the shield layer 6 and the conductive layer 7 and the current (high-frequency current 25) of the high-frequency power for the bias potential formation supplied to the electrode block 1 is suppressed from flowing to the heater feed line 22. That is, because the high-frequency current 25 flows through the surface of the conductor by a skin effect, in this embodiment, the top surface and the end portion of the outer circumferential side of the heat generation layer 5 are covered with the shield layer 6 configured using a conductive material having a thickness more than a skin depth where the high-frequency current 25 flows, the heat generation layer 5 is surrounded, and the high-frequency current 25 is suppressed from flowing to the heat generation layer 5. Thereby, heat generation of the heater feed line 22 can be suppressed. As a result, the heater can be mounted on the sample stage 101 and a value of a higher range can be used as the frequency of the high-frequency power for the bias potential formation.

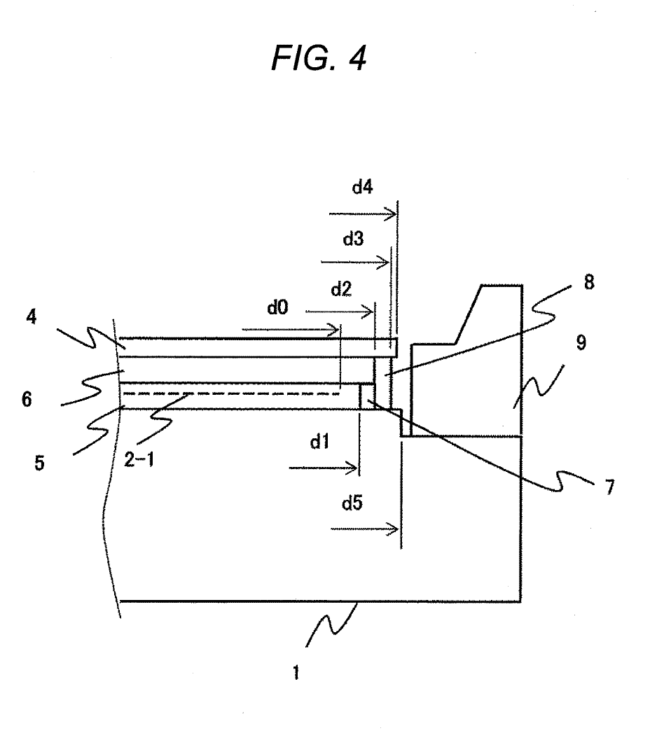

A dimension of the sample stage 101 according to this embodiment will be described in detail using FIG. 4. FIG. 4 is a longitudinal cross-sectional view schematically illustrating a configuration of the sample stage of the plasma processing device according to the embodiment illustrated in FIG. 1. In FIG. 4, a dimension of a film structure of a plurality of layers of the sample stage 101 according to this embodiment will be described.

In this example, a configuration in which the conductive layer 7 is disposed between the portion of the outer circumferential side of the shield layer 6 and the top surface of the convex portion of the electrode block 1 and the heat generation layer 5 is disposed in the conductive layer 7 is included. The film-like resistor 2-1 for the heat generation is disposed in the insulator film 2-2 configuring the heat generation layer 5. From this, a diameter dl of the heat generation layer 5 on the convex portion of the circular cylindrical shape of the center portion of the electrode block 1 and a diameter dO of an outermost circumferential edge of the resistor 2-1 for the heat generation disposed in the circular shape or the multiple circular arc shape around the center axis of the convex portion in the heat generation layer 5 are smaller than a diameter d2 of the shield layer 6 covering the heat generation layer 5 and are smaller than a diameter d4 of the electrostatic adsorption layer 4 disposed on the shield layer 6 and a diameter of the sample W disposed and held on a top surface of the electrostatic adsorption layer 4. In addition, the diameter d2 of the shield layer 6 is smaller than the diameter d4 of the electrostatic adsorption layer 4 and the insulating layer 8 is disposed between the back surface of the portion of the outer circumferential side of the electrostatic adsorption layer 4 and the top surface of the convex portion of the electrode block 1, such that the insulating layer 8 covering the outer conferential surfaces of the shield layer 6 and the conductive layer 7 stops in the back surface of the electrostatic adsorption layer 4 and can suppress an input of the particles of the plasma 43.

In addition, in this embodiment, the diameter d3 of the insulating layer 8 and the diameter d4 of the electrostatic adsorption layer 4 are preferably smaller than a diameter d5 of the top surface of the convex portion of the circular shape of the electrode block 1. The reason is as follows. When a position deviation of a radial direction occurs in a susceptor ring 9 disposed on the recessed portion of the outer circumferential side of the electrode block 1 at the outer circumferential side of the electrostatic adsorption layer 4, the susceptor ring 9 is suppressed from contacting the electrostatic adsorption layer 4 or the insulating layer 8, because displacement of the susceptor ring 9 is suppressed at a position of the diameter d5 of the top surface of the electrode block 1.

Because the electrostatic adsorption layer 4 configured using the dielectric such as ceramics or the insulating layer 8 is more fragile than the metallic electrode block 1, cracking or chipping occurs due to a contact of the susceptor ring 9 and the electrostatic adsorption layer 4 or the insulating layer 8, fragments or particles occur, and a foreign material or contamination occur. Therefore, the contact should be avoided. The susceptor ring 9 is configured using silicon, quartz, and alumina, according to a condition of the etching process.

The circular heat generation layer 5 according to this embodiment is disposed on the top surface of the convex portion of the circular shape of the metallic electrode block 1 electrically connected to a ground electrode and having a ground potential, the outer side of the outer circumferential edge of the heat generation layer 5 is surrounded with the conductive layer 7 having conductivity, the conductive layer 7 and an upper portion of the heat generation layer 5 are covered with the shield layer 6 having the conductivity such as the metal, and a surrounding portion of the heat generation layer 5 is surrounded with the member having the conductivity. A dimension of the member to cover the heat generation layer 5 is set to a value more than the skin depth where the current of the high-frequency power supplied to the processing chamber 33 flows by the skin effect.

For example, d2−d1 (a distance between a radius position of an outermost circumferential edge of the conductive layer 7 and a radius position of an outermost circumferential edge of the heat generation layer 5) to be a width of the conductive layer 7 with respect to the radial direction of the convex portion of the electrode block 1 is more than the skin depth. In addition, a thickness of a vertical direction of the shield layer 6 is more than the skin depth of the current by the high-frequency power.

By this configuration, in this embodiment, the current of the high-frequency power is suppressed from flowing to the resistor 2-1 for the heat generation in the heat generation layer 5. Thereby, a situation where the current of the high-frequency power flows to the heater feed line 22 supplying power to the resistor 2-1 for the heat generation, the heat is generated in the heater feed line 22, and performance of the heater feed line is deteriorated can be suppressed from occurring. As a result, mounting of the heater on the sample stage 101 and processing of the sample W using the high-frequency power for the bias potential formation with the frequency of the high range can be realized.

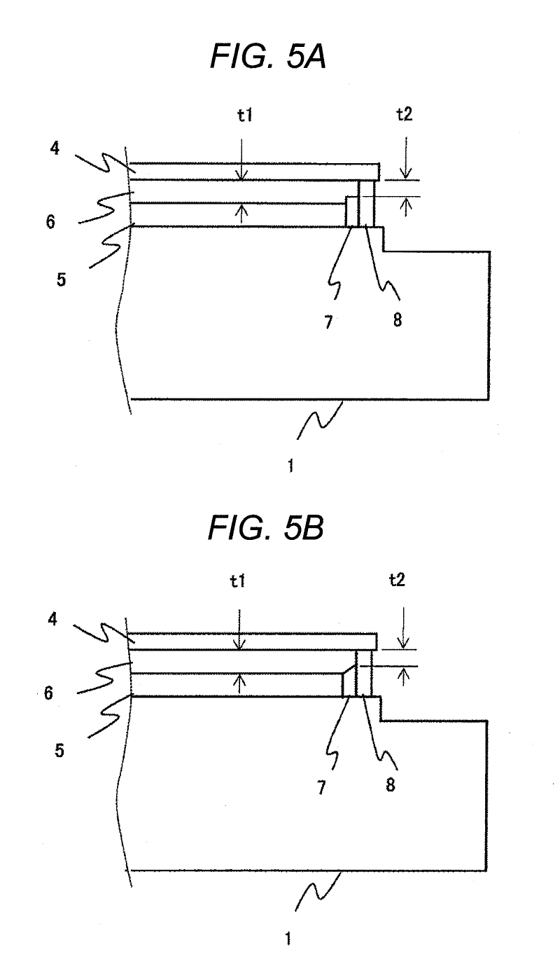

A modification of the embodiment will be described using FIGS. 5A and 5B. FIGS. 5A and 5B are longitudinal cross-sectional views schematically illustrating a configuration of a sample stage of a plasma processing device according to a modification of the embodiment illustrated in FIG. 1.

In the embodiment, when the sample stage 101 is heated by heat generation from the heat generation layer 5 of the sample stage 101, the temperature of the electrode block 1 becomes the predetermined temperature by the cooling medium flowing through the cooling medium flow channel 11. In the case in which the temperature of the shield layer 6 is higher than the temperature of the top surface of the electrode block 1 (or the inner wall surface of the cooling medium flow channel 11), if there is not a large difference in thermal expansion coefficients of the materials forming the electrode block 1 and the shield layer 6, a thermal expansion amount of the shield layer 6 also becomes more than a thermal expansion amount of the electrode block 1.

In this case, stress by a difference of the thermal expansion amounts occurs in the conductive layer 7. In the case in which a conductive adhesive is used in the conductive layer 7, if stress more than bonding strength of the conductive adhesive occurs in the conductive layer 7, exfoliation occurs in the conductive layer 7, conduction between the electrode block 1 and the shield layer 6 is deteriorated, and the high-frequency current 25 cannot be suppressed from flowing to the heat generation layer 5. To suppress the above situation from occurring, the conductive layer 7 according to this example is formed in a shape to alleviate the stress by the difference of the thermal expansion amounts between the members connected to the conductive layer 7 in a vertical direction.

That is, as illustrated in FIG. 5A, the shield layer 6 according to this example has a step in which the thickness of the portion of the outer circumferential edge is smaller than the thickness of the inner circumferential side with respect to the radial direction of the electrode block 1 and the back surface of the portion of the outer circumferential edge is recessed (in an upward direction in the drawing). The conductive layer 7 is disposed in a space of the lower side of the recessed portion and the outer side of the outer circumferential wall of the heat generation layer 5 with the step so as to fill this space and has the thickness over both sides. The stress occurring in the conductive layer 7 by the difference of the thermal expansion amounts of the members connected in the vertical direction is alleviated by the conductive layer 7 and the exfoliation and flowing of the high-frequency current 25 to the heater feed line 22 by the exfoliation are reduced.

FIG. 5B illustrates another modification where the portion of the outer circumferential side of the shield layer 6 has a tapered shape in which the thickness decreases gradually in the radial direction. Similar to the example of FIG. 5A, the conductive layer 7 is disposed in the space of the back side of the outer circumferential edge portion where the thickness of the shield layer 6 decreases and the outer circumferential side of the heat generation layer 5 to contact both surfaces so as to fill this space and the thickness of the conductive layer 7 increases in a radial direction according to the tapered shape of the back surface of the outer circumferential edge portion of the shield layer 6. Even in this configuration, similar to FIG. 5A, the stress occurring in the conductive layer 7 can be alleviated and the exfoliation and flowing of the high-frequency current 25 to the heater feed line 22 by the exfoliation can be suppressed.

By the shapes of FIGS. 5A and 5B, an area of an adhesive surface of the side of the shield layer 6 can be increased without changing the width of the radial direction of the conductive layer 7. In this example, the thickness of the vertical direction of the shield layer 6 decreases in the radial direction and the thickness of the outermost circumferential edge is minimized. That is, the thickness t1 of the center side of the shield layer 6 is more than the thickness t2 of the outer circumferential edge portion. In addition, the thickness t1 and t2 of the shield layer 6 is set to a value more than the skin depth of the current of the high-frequency power supplied to the processing chamber 33.

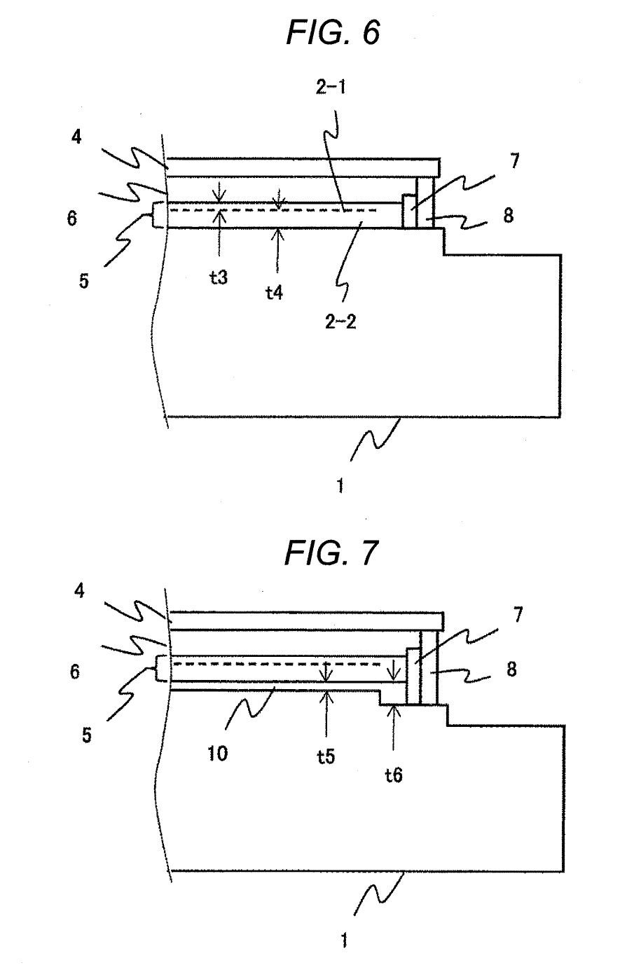

Next, the configuration of the heat generation layer 5 of the sample stage 1 according to the modification will be described in detail using FIG. 6. FIG. 6 is a longitudinal cross-sectional view schematically illustrating a configuration of a heat generation layer of the sample stage according to the modification illustrated in FIGS. 5A and 5B.

In this example, the heat generation layer 5 has a configuration in which the film-like resistor 2-1 for the heat generation is covered with the insulator film 2-2. Generally, thermal conductivity is relatively small in ceramics such as alumina and resin such as polyimide used for the insulator film 2-2. Therefore, in this example, the resistor 2-1 for the heat generation is disposed at a position where the thickness t3 of the insulator film 2-2 on the resistor 2-1 for the heat generation and the thickness t4 of the insulator film 2-2 below the resistor 2-1 for the heat generation satisfy t4>t3.

By this configuration, the heat generated by the resistor 2-1 for the heat generation is transmitted more efficiently to the side of the sample W on the resistor 2-1 for the heat generation. This configuration is realized in the heat generation layer 5 of the sample stage 101 according to the embodiment illustrated in FIG. 3, so that the same function and effect can be achieved. The thickness (thickness of the vertical direction in the drawing) of the heat generation layer 5 according to this embodiment is about several mm or less, preferably, 1 mm or less.

As described above, a value of a radius position dl of the outermost circumferential edge of the heat generation layer 5 from the center axis of the convex portion of the electrode block 1 is larger than a value of a radius position dO of the outermost circumferential edge of the resistor 2-1 for the heat generation disposed in the heat generation layer 5. A distance d1−d0 of the outermost circumferential edge of the resistor 2-1 for the heat generation and the outer circumferential edge of the heat generation layer 5 corresponds to a width (thickness of a horizontal direction in the drawing) of the radius direction of the insulator film 2-2 existing in the outermost circumferential edge portion of the heat generation layer 5.

Even in this example, the distance d1−d0 is more than the skin thickness with respect to the current of the high-frequency power. In addition, each of the thickness t3 and t4 of the upper and lower portions of the insulator film 2-2 is also more than the skin thickness with respect to the current of the high-frequency power. By this configuration, the current of the high-frequency power flowing through the surfaces of the electrode block 1, the conductive layer 7, and the shield layer 6 is suppressed from flowing to the resistor 2-1 for the heat generation and the heat is suppressed from being generated in the heater feed line 22.

Next, a configuration of an adhesive layer to adhere the heat generation layer 5 and the electrode block 1 in another modification of the embodiment will be described using FIG. 7. FIG. 7 is a longitudinal cross-sectional view schematically illustrating a configuration of a sample stage according to another modification of the embodiment illustrated in FIG. 3. Particularly, in this example, the configuration of the adhesive layer to adhere the electrode block 1 and the heat generation layer 5 of the sample stage 101 will be described.

In FIG. 7, the heat generation layer 5 and the top surface of the convex portion of the circular shape of the electrode block 1 are adhered with an adhesive layer 10 therebetween. As an adhesive configuring the adhesive layer 10, a silicon-based adhesive or an epoxy-based adhesive is used.

Because the adhesive has relatively low thermal conductivity, the adhesive layer 10 can be used as a heat insulating layer by selecting the thickness of the adhesive layer 10 appropriately. Meanwhile, in the configuration of FIG. 3, the conductive layer 7 or the insulating layer 8 is disposed on the outer circumferential side of the heat generation layer 5 or the shield layer 6 and a diameter of the heat generation layer 5 is smaller than a diameter of the electrostatic adsorption layer 4 (d4>d1) as illustrated in FIG. 4.

For this reason, the heat generation layer 5 cannot be disposed to the same position as the radius position of the outer circumferential edge of the electrostatic adsorption layer 4, a heat transfer amount from the heat generation layer 5 in a place (a region between d4 and d1) to be an outer circumferential edge portion of the electrostatic adsorption layer 4 and closer to the outside than the outer circumferential edge (the diameter d1) of the heat generation layer 5 is smaller than a heat transfer amount of the region closer to the center side than the diameter d1, and a value of the temperature in the corresponding region or a variation from the center side of a distribution thereof increases. Therefore, in this example, the adhesive layer 10 is disposed such that the thickness of the vertical direction of the adhesive layer 10 is different with respect to the radial direction of the electrode block 1. Particularly, the thickness t6 of the outermost circumferential portion is smaller than the thickness t5 of the portion closer to the center side (than the diameter d1) (t6>t5).

To realize the distribution of the thickness of the adhesive layer 10 with respect to the radial direction, a recessed portion of a ring shape with a step is disposed in the outer circumferential end portion in the top surface of the convex portion of the center portion of the electrode block 1, the adhesive layer 10 is disposed on the top surface of the convex portion of the electrode block 1 from the center side to the recessed portion, the top surface of the adhesive layer 10 has a flat shape from the center portion to the outer circumferential end portion, and the distribution of the thickness of t6>t5 is realized. By the distribution of the thickness in which the thickness of the outer circumferential side increases, movement of the heat transmitted from the heat generation layer 5 to the lower side via the adhesive layer 10 is suppressed in the portion of the outer circumferential side of the heat generation layer 5, an amount of movement of the heat transmitted to the upper side is increased, and the temperature of the top surface of the electrostatic adsorption layer 4 or the sample W or heating efficiency in the outer circumferential portion of the heat generation layer 5 is increased.

As illustrated in FIG. 7, the heat generation layer 5 disposed over the recessed portion with the step disposed on the portion of the outer circumferential side of the top surface of the convex portion of the center portion of the electrode block 1 and the insulating layer 8 disposed to cover the outer circumferential surfaces of the conductive layer 7 and the shield layer 6 disposed to cover the outer circumferential surface of the adhesive layer 10 below the heat generation layer 5 are disposed between the top surface of the recessed portion and the back surface of the outer circumferential edge portion of the electrostatic adsorption layer 4. This configuration is the same as the configurations illustrated in FIGS. 3 to 5B.

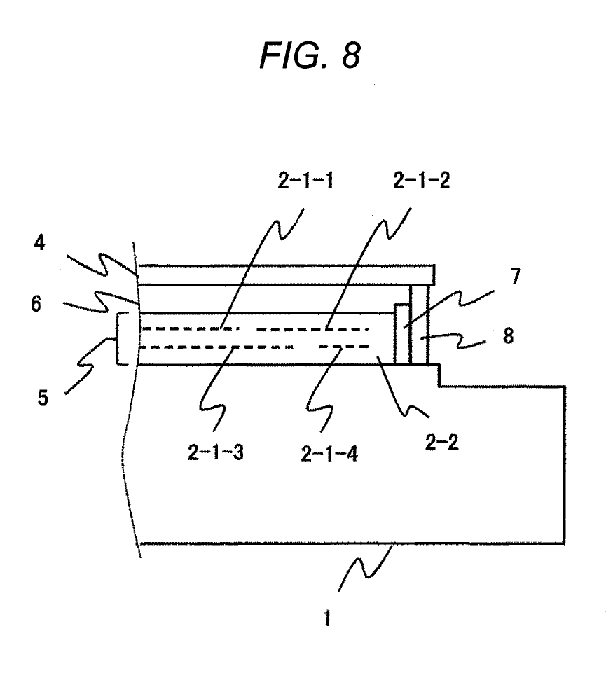

Next, other modification of the embodiment will be described using FIG. 8. FIG. 8 is a longitudinal cross-sectional view schematically illustrating a configuration of a sample stage of a plasma processing device according to other modification of the embodiment illustrated in FIG. 3.

In this example, both the electrode block 1 and the shield layer 6 are electrically connected by disposing the conductive layer 7. For this reason, a voltage is suppressed from becoming hard to be applied to a plasma sheath formed on the sample W by impedance of the heat generation layer 5, when the high-frequency power for the bias formation is applied from the high-frequency power supply 21 to the electrode block 1.

From this, the heat generation layer 5 has a lamination configuration in which a plurality of resistors 2-1 for heat generation are overlapped and disposed vertically in the insulator film 2-2. As a result, even when the entire thickness of a vertical direction of the insulator film 2-2 of the heat generation layer 5 increases, the impedance between the electrode block 1 and the shield layer 6 can be suppressed from being affected. FIG. 8 illustrates an example of the configuration in which two of the resistors 2-1 for the heat generation are overlapped and disposed vertically, which is considered on the basis of information acquired from the above.

In FIG. 8, the heat generation layer 5 has a configuration in which an upper-step inner heat generator 2-1-1, an upper-step outer heat generator 2-1-2, a lower-step inner heat generator 2-1-3, and a lower-step outer heat generator 2-1-4 are disposed in the insulator film 2-2 and are covered with the insulator film 2-2. In the upper-step heat generators and the lower-step heat generators, a division position between the inner side and the outer side is different in plane. When the upper-step and lower-step heat generators are used independently or are used together, different temperature distributions of the surfaces of the electrostatic adsorption layer 4 and the sample W disposed on the top surface of the electrostatic adsorption layer 4 can be realized.

To reduce a variation of a processing shape as a result of the etching process with respect to an in-plane direction of the surface of the sample W, the temperature of the surface of the sample W at the time of etching and a distribution thereof need to be maximally matched with a temperature and a distribution thereof in which a desired processing result can be obtained. The temperature distribution is different according to a kind of a process target layer and a process condition. As in this example, the heat generation layer 5 having the multilayered structure is provided, so that a range in which the temperature of the sample W and the distribution with respect to the in-plane direction thereof can be realized is widened, and it is possible to correspond to multiple kinds and process conditions in a wide range.

In the embodiment described above, the sample stage 101 has the film structure of the plurality of layers in which the heat generation layer 5, the shield layer 6, the conductive layer 7, the insulating layer 8, the electrostatic adsorption layer 4, and the adhesive layer 10 are provided on the top surface of the convex portion of the circular cylindrical shape of the center portion of the discoid or circular cylindrical electrode block 1 and has the configuration in which the heat generation layer 5 is covered with the shield layer 6 and the conductive layer 7. In these configurations, the current (high-frequency current 25) of the high-frequency power for the bias potential formation supplied to the electrode block 1 is suppressed from flowing to the heater feed line 22 via the resistor 2-1 for the heat generation disposed in the insulator film 2-2 of the heat generation layer 5. Thereby, the heat generation of the heater feed line 22 is suppressed. As a result, both mounting of the heater of the sample stage 101 and a high frequency of the high-frequency power for the bias potential formation can be realized.

An applicable range of the frequency of the high-frequency power is widened, so that high-frequency powers of different frequency bands can be superposed and can be supplied to the electrode block 1. The heat generation layer 5 of the sample stage 101 may include a multilayered heater. Thereby, because controllability of the temperature with respect to the in-plane direction is improved, an optimal temperature distribution can be realized according to multiple etching process conditions.

In the embodiment and the modifications, when the chamber cleaning is performed after processing of the sample W in the processing chamber 33 ends, rare gas such as argon is introduced into the processing chamber 33, the plasma is formed, and the top surface of the sample stage 101 is exposed to the plasma by the rare gas. However, occurrence of problems such as a temporal change of conductivity of the conductive layer 7 and contamination in the vacuum processing chamber by the cut conductive material is suppressed by using a configuration in which the insulating layer 8 is disposed on the outer circumferential portion of the conductive layer 7 and the conductive layer 7 is protected from the plasma. Thereby, a process in which the frequency of the high-frequency power for the bias potential formation and the temperature of the sample and the distribution thereof are optimized can be realized and a plasma processing device in which reliability is improved by suppressing occurrence of materials or particles causing foreign materials in the processing chamber 33 over a long period can be realized.

In this embodiment, the example of the case in which the first and second embodiments are applied to the microwave ECR plasma etching device has been described. However, even when a method of generating the plasma is other method such as inductive coupling and capacitive coupling, it is needless to say that the effect of the sample stage according to the present invention is obtained.

The sample stage of the vacuum processing device suggested by the present invention is not limited to the embodiment of the plasma processing device and is applicable to other device needing precise wafer temperature management, such as an ashing device, a sputter device, an ion implantation device, a resist coater, a plasma CVD device, a flat panel display manufacturing device, and a solar battery manufacturing device.

1. A plasma processing device comprising:
a processing chamber which is disposed in a vacuum vessel and is compressed internally;
a sample stage which is disposed in a lower portion in the processing chamber and on which a sample of a process target is disposed and held; and
a mechanism for forming plasma in the processing chamber, wherein
the sample stage includes a metallic electrode block to which high-frequency power is supplied from a high-frequency power supply, a dielectric heat generation layer which is disposed on a top surface of the electrode block and in which a film-like heater receiving power and generating heat is disposed, a conductor layer which is disposed to cover the heat generation layer, a ring-like conductive layer which is disposed to surround the heat generation layer at an outer circumferential side of the heat generation layer, contacts the conductor layer and the electrode block, and electrically connects the conductor layer and the electrode block, and an electrostatic adsorption layer which is disposed to cover the conductor layer and generates electrostatic force to electrostatically adsorb the sample disposed on a top surface thereof, and
the conductor layer and the ring-like conductive layer have dimensions more than a skin depth of a current of the high-frequency power and the electrode block is maintained at a predetermined potential during processing of the sample.

2. The plasma processing device according to claim 1, wherein:
a thickness of dielectric materials at outer circumference of the film-like heater of the heat generation layer and on and below the film-like heater is more than the skin depth.

3. The plasma processing device according to claim 1, wherein:
the conductor layer has a different thickness of a vertical direction with respect to a radial direction of the electrode block and has a minimum thickness at an outermost circumferential edge.

4. The plasma processing device according to claim 1, wherein:
a thickness of a dielectric material on the film-like heater of the heat generation layer is smaller than a thickness of a dielectric material below the film-like heater.

5. The plasma processing device according to claim 1, wherein:
an adhesive layer disposed between the electrode block and the heat generation layer has a different thickness of a vertical direction with respect to a radial direction of the electrode block and has a maximum thickness at an outermost circumferential edge.
